(19) United States
(12) Patent Application Publication
(10) Pub. No.: US 2026/0261217 A1
(43) Pub. Date: Sep. 3, 2026

(54) LOW-IMPEDANCE CLAMPING CIRCUIT FOR A SEMICONDUCTOR SWITCHING ELEMENT IN A CONVERTER

(71) Applicant: ZF Friedrichshafen AG, Friedrichshafen (DE)

(72) Inventors: Ruben Bärenweiler, Markdorf (DE); Manuel Raimann, Salem (DE)

(73) Assignee: ZF Friedrichshafen AG, Friedrichshafen (DE)

(21) Appl. No.: 18/839,316

(22) PCT Filed: Feb. 14, 2023
(86) PCT No.: PCT/EP2023/053653

§ 371 Date: Aug. 16, 2024

(30) Foreign Application Priority Data
Feb. 17, 2022 (DE) 10 2022 201 640.8

(51) Int. Cl. H02M 7/537; B60K 6/22; B60L 15/00; H02H 7/08; H02M 1/08; H02M 1/32

(52) U.S. Cl. CPC H02M 7/537; B60L 15/007; H02H 7/08; H02M 1/08; H02M 1/32; B60K 6/22; B60Y 2200/91; B60Y 2200/92; B60Y 2400/61

(57) ABSTRACT

A clamping circuit for a power module, wherein the power modules each contain one or more semiconductor switches connected in parallel and a plurality of terminals for an input current and an output current, as well as a plurality of signal pins for transmitting control signals generated by a driver module to the power modules, wherein the semiconductor switches, terminals, and signal pins in the power modules form a module circuit, wherein the clamping circuit contains a clamping switch between a gate terminal and a reference potential terminal on a semiconductor switch, wherein the clamping switch is integrated in the module circuit in the power module.

### CROSS-REFERENCE TO RELATED APPLICATIONS

This application is a U.S. national stage application under 35 U.S.C. § 371 of PCT Application No. PCT/EP2023/053653, filed on Feb. 14, 2023, and published as WO 2023/156395 A1 on Aug. 24, 2023, which claims priority from German Application No. DE 10 2022 201 640.8, filed on Feb. 17, 2022, the entirety of which are each hereby fully incorporated by reference herein.

### FIELD

The invention relates to the field of power electronics for partially or entirely electrified vehicles. In particular, the invention relates to a converter, e.g. an inverter or a rectifier, with which electricity is provided to an electric drive in an electric vehicle or hybrid vehicle.

### BACKGROUND

There are purely electric vehicles and hybrid vehicles in the prior art that are powered exclusively or partially by one or more electric motors forming drive units. To supply the electric motors in these electric vehicles or hybrid vehicles with electricity, the vehicles contain electricity storage units, in particular rechargeable batteries. These batteries are DC power sources. The electric motors normally require AC voltage. For this reason, power electronics with a so-called inverter are normally interconnected between the batteries and electric motors in an electric vehicle or hybrid vehicle.

These inverters usually contain semiconductor switches, typically made of transistors. The semiconductor switches can have different degrees of integration, specifically as discrete switches with a low degree of integration, which can be scaled to a greater extent, power modules with a high degree of integration, but which can be scaled to a lower extent, or half bridges, in which the degree of integration and scalability range between that of individual switches and power modules. Each half bridge has a high side switching position (hereinafter “high side”), which has a higher electrical potential, and low side switching position (hereinafter “low side”), which has a lower electrical potential. The high side and low side can each contain one or more individual switches/semiconductor switches, which are connected in parallel.

Depending on the design of the semiconductor switch, it can be switched on and off by the current or voltage applied thereto. The semiconductor switches are preferably switched by pulse-width modulation (PWM) to obtain a sinusoidal temporal curve in the current phases. In this manner, an input direct current can be converted to a multiphase output current (alternating current) with multiple current phases, with which the electric drive (electric motor) in an electric or hybrid vehicle can be powered.

There are parasitic elements in converter systems. They can exist in the form of parasitic capacitors between a control terminal (gate) and a controlled terminal (drain) for the semiconductor switch (IGBT or MOSFET). In particular, during high negative slew rates for the drain-source voltage of a semiconductor switch (e.g. on the high side), current can flow toward the gate in the complementary semiconductor switch (e.g. on the low side) in the bridge configuration. The current flow is caused by the Miller capacitance between the reference potential terminal (source terminal) and the controlled terminal (drain terminal). For this reason, it is also called “Miller current.” The amperage of the Miller current depends on both the Miller capacitance and the voltage fluctuation in the drain-source voltage at complementary semiconductor switches.

Consequently, a voltage spike (“Miller spike”) occurs at the gate in the complementary semiconductor switch caused by the decrease in voltage along the path of the Miller current. The voltage drop increases with the impedance of this path. When these voltage spikes reach a specific threshold for the semiconductor switch in question, they can be unintentionally turned on (a so-called “Miller turn on”), resulting in a short circuit between the high side and low side, destroying the semiconductor switch.

### SUMMARY

An object of the present disclosure is to create a clamping circuit in which the above disadvantages are at least partially overcome.

This problem is solved by the clamping circuit, converter, electric axle drive, and vehicle according to the present disclosure. Advantageous embodiments and designs can also be derived from the present disclosure.

The present disclosure relates to a clamping circuit for a converter with which an electric axle drive in an electric vehicle and/or hybrid vehicle is operated. The converter receives an input current and generates an output current based thereon.

The converter is preferably a DC/AC inverter. With an inverter, the input current is a direct current supplied by a DC voltage source, and the output current is an alternating current with numerous phases. The converter can also be a DC/DC rectifier. With a rectifier, the input current is a direct current from a DC voltage source (either a charging station or a vehicle battery/fuel cell), and the output current is a direct current that differs from the input current (such as a charging current for charging a high-voltage vehicle battery), with which a vehicle battery is preferably charged.

The converter comprises numerous (e.g. three) phase units, each of which is assigned a phase, or is designed to generate its own current phase. The phase units each have one or more power modules, which each contain numerous semiconductor switches in the form of MOSFETs or IGBTs. The fundamental material used for the semiconductor switches is preferably a wide-bandgap semiconductor (WBGS) such as silicon carbide (SIC) or gallium nitride (GaN).

The power modules are designed as half bridge modules, for example. Each half bridge module has a high side and a low side, each of which contains one or more semiconductor switches connected in parallel. These semiconductor switches 12 can also be placed in a power module that is not a half bridge module, in which case the semiconductor switches 12 can be interconnected externally to a half bridge or a multilevel system (containing two or more levels).

If the phase unit contains just one half bridge module, the high side forms a high side device for the entire phase unit, and its low side forms a low side device for the entire phase unit. If a phase unit contains numerous half bridge modules, because of the parallel connection, the high sides form a high side device for the entire phase unit, and the low sides form a low side device for the entire phase unit.

There are numerous terminals on each half bridge module for the input current and the output current. There are also numerous signal pins on each half bridge module for transmitting semiconductor switch control signals. The semiconductor switches, terminals, and signal pins in each half bridge module form a module circuit. All of the electronic components in each half bridge module preferably form the module circuit. Each of the half bridge modules are preferably insulated (e.g. by spraying them with an injection molding material), such that only the terminals and signal pins protrude therefrom and can be contacted from outside.

The converter also contains a driver module composed of numerous electronic components typically populating a printed circuit board. The electronic components generate control signals sent to gate terminals on the respective semiconductor switches in order to switch them on and off.

The converter contains a clamping circuit (“Active Miller Clamping” circuit, or AMC circuit) with which the control, or gate, terminal in a semiconductor switch is short circuited (or “clamped”) by a reference potential, or source, terminal. The clamping circuit contains a clamping switch between the gate and reference potential terminals in the semiconductor switch in question. The clamping switch is preferably a transistor, in particular a MOSFET, e.g. an n-MOSFET. In this case, the clamping switch contains a clamping terminal (gate terminal) for a clamping signal, and both a positive and negative terminal (drain and source terminals). The clamping signal is provided by a control unit for the clamping switch, preferably integrated in the driver module. By activating the clamping switch in a targeted manner, active Miller clamping (AMC) is preferably activated only when switching the complementary switch (high side or low side) in the half bridge. The AMC results in an additional current path for the Miller current to the reference potential terminal, for counteracting the voltage spikes, or Miller spikes, described above.

With the present disclosure, the clamping circuit is placed in a half bridge module containing the relevant semiconductor switch. This means that the clamping circuit is an integral part of the module circuit corresponding to this half bridge module. This reduces the length of the path for the Miller current, thus reducing the impedance thereof. This also suppresses the Miller spikes. Consequently, the semiconductor switches can function at their maximum speeds, resulting in converters or inverters that can be used where faster switching is required.

In one embodiment, a first signal pin in the half bridge module is dedicated to the clamping switch with which a clamping signal generated by a control unit spatially separated from the half bridge module is sent to the clamping switch. The first signal pin can be in a lead frame containing the other signal pins for the semiconductor switch in question. This does not require an additional production step for the clamping switch signal pin. The converter can thus be produced more easily.

In another embodiment, the first signal pin extends from a clamping circuit terminal for the clamping switch to the control unit. The clamping switch is therefore on a side of the first signal pin facing the semiconductor switch in question. This shortens the path for the Miller current, thus further suppressing Miller spikes.

In another embodiment, the control unit is integrated in the driver module, which is separate from the half bridge module, and spaced apart therefrom. This reduces the complexity and production costs for the converter. In addition, parallelize numerous half bridge modules can be parallelized with a single driver module. The control unit can also be taken accounted for and provided when producing the driver module. There is therefore no need for a separate production step for the control unit, thus reducing production costs for the converter.

In another embodiment, the half bridge module is coated with an insulating material, from which the signal pins for the half bridge modules extend, and which also contains the clamping circuit. By this means, the clamping circuit is contained and fully integrated in the half bridge module, better protecting it from environmental effects.

In another embodiment, the clamping circuit also contains a capacitor between the clamping switch and the gate terminal or the reference potential terminal for the associated semiconductor switch.

If the capacitor is between the clamping switch and the gate terminal for the associated semiconductor switch, a second signal pin is connected at the module side to both the capacitor and the gate terminal for the semiconductor switch, and a third signal pin is connected at the module side to both a negative terminal in the clamping switch and the reference potential terminal for the associated semiconductor switch, in which case the first signal pin is dedicated exclusively to the clamping switch, and a diode (referred to as a “body diode”) is intrinsically built into the clamping switch. This placement of the capacitor in relation to the clamping switch has advantages in that only three signal pins are needed for the semiconductor switch and the clamping switch, and only one further signal pin is needed for the clamping switch.

If the capacitor is between the clamping switch and the reference potential terminal for the associated semiconductor switch, a signal pin is connected at the module side to both a positive terminal for the clamping switch and the gate terminal for the associated semiconductor switch, and an additional signal pin is connected at the module side to both a negative terminal for the clamping switch and the capacitor, while another signal pin is connected at the module side to both the capacitor and the reference potential terminal for the associated semiconductor switch.

The present disclosure also relates to a half bridge module containing such a clamping circuit, and a converter (inverter or rectifier) containing numerous such half bridge modules. The present disclosure also relates to a corresponding electric axle drive containing a converter obtained with the present disclosure, and a vehicle that has such an electric axle drive. This results in the advantages described in conjunction with the clamping circuit obtained with the present disclosure for both the electric axle drive and the vehicle obtained with the present disclosure.

The present disclosure shall be explained below in reference to the exemplary embodiments shown in the drawings.

### BRIEF DESCRIPTION OF THE DRAWINGS

FIG. 1 shows a schematic, highly simplified circuit diagram containing a module circuit for a half bridge module, a driver module, and a clamping circuit integrated in the module circuit;

FIG. 2 shows a schematic circuit diagram containing a module circuit for the half bridge module, the drive module, and a clamping circuit integrated in the module circuit, according to one embodiment;

FIG. 3 shows an enlargement of the half bridge module shown in FIG. 2;

FIG. 4 shows a schematic circuit diagram containing a module circuit for the half bridge module, the drive module, and a clamping circuit integrated in the module circuit, according to another embodiment; and

FIG. 5 shows an enlargement of the half bridge module shown in FIG. 4.

### DETAILED DESCRIPTION

Identical objects, functional units and comparable components have the same reference symbols in all of the figures. These objects, functional units, and comparable components are identical with regard to their technical features, as long as not otherwise explicitly or implicitly specified.

The present disclosure relates to a converter for supplying electricity to the electric drive in an electric vehicle or hybrid vehicle. When in use, an input current is supplied to the converter, from which it generates an output current. The converter is preferably a DC/AC inverter. With an inverter, the input current is a direct current from a DC voltage source, and the output current is an alternating current with numerous phases. The converter can also be a DC/DC rectifier (converter). With a rectifier, the input current is a direct current from a DC voltage source (either a charging station or a vehicle battery/fuel cell), and the output current is a direct current that differs from the input current (such as a charging current for a high voltage vehicle battery) with which a vehicle battery is charged.

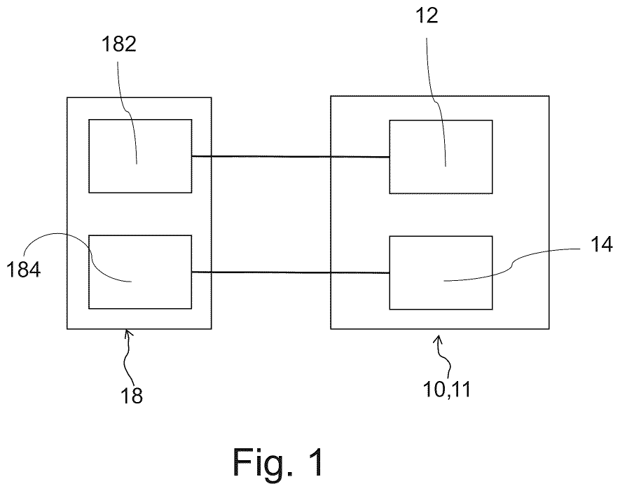

The converter has numerous phase units (e.g. three), each of which is assigned a specific current phase, or is designed to generate a specific current phase. The phase units each have one or more power modules 10, 10A-B (see FIGS. 1-3), each of which contains numerous semiconductor switches 12 in the form of MOSFETs, HEMTs, or IGBTs, for example. The material forming the semiconductor switches 12 is preferably a wide-bandgap semiconductor (WBGS) such as silicon carbide (SIC) or gallium nitride (GaN).

The power modules 10, 10A-B can form half bridge modules. Each half bridge module 10, 10A-B has a high side and a low side, each of which contains numerous semiconductor switches 12 connected in parallel. These semiconductor switches 12 can also be used in a power module that is not a half bridge module, in which case they can be interconnected externally to a half bridge or a multilevel system.

If a phase unit contains a single half bridge module 10, 10A-B, its high side forms a high side device for the entire phase unit, and its low side forms a low side device for the entire phase unit. If a phase unit contains numerous half bridge modules 10, 10A-B, the high sides are connected in parallel to form a high side device for the entire phase unit, and the low sides are connected in parallel to form a low side device for the entire phase unit.

There are numerous terminals on each half bridge module 10, 10A-B for the input current and the output current. There are also numerous signal pins 16a-g on each half bridge module 10, 10A-B for control signals for the semiconductor switches 12. The semiconductor switches 12, terminals, and signal pins 16a-g in each half bridge module 10, 10A-B form a module circuit 11. Preferably, all of the electronic components in each half bridge module 10, 10A-B collectively form the module circuit 11. The half bridge modules 10, 10A-B are preferably insulated (by an injection molded coating), such that only the terminals and signal pins 16a-g protrude from the insulation and be contacted.

The converter also contains a driver module 18 that has numerous electric components, typically populating a printed circuit board. The electric components generate control signals that are sent to a gate terminal 122 on the respective semiconductor switches 12 with which the semiconductor switches 12 are switched on and off.

FIG. 1 shows a schematic, highly simplified circuit diagram containing a module circuit 11, a half bridge module 10, a driver module 18, and a clamping circuit 14 integrated in the module circuit 11. The clamping circuit 14 (“Active Miller Clamping” circuit, or AMC circuit) is designed to short circuit (or “clamp”) the gate terminal 122 in a semiconductor switch 12, or the source terminal thereof, with a reference potential 126. The clamping circuit 12 for the present disclosure is in the half bridge module 10 containing the semiconductor switch 12 in question. This means that the clamping circuit 14 is an integral part of the module circuit 11 corresponding to this half bridge module 10. This shortens the path for the Miller current, such that the impedance in the Miller current path is also reduced. This can further suppress the Miller spikes. This allows the half bridge elements 12 to function at their maximum speed, such that the converter, or inverter, can also be used where faster switching is required.

The driver module 18 contains a first control unit 182 for the semiconductor switches 12 in the half bridge module 10. The clamping circuit 14 is switched by a clamping circuit signal generated by a second control unit 184 that is preferably integrated in the driver module 18, as shown in FIG. 1.

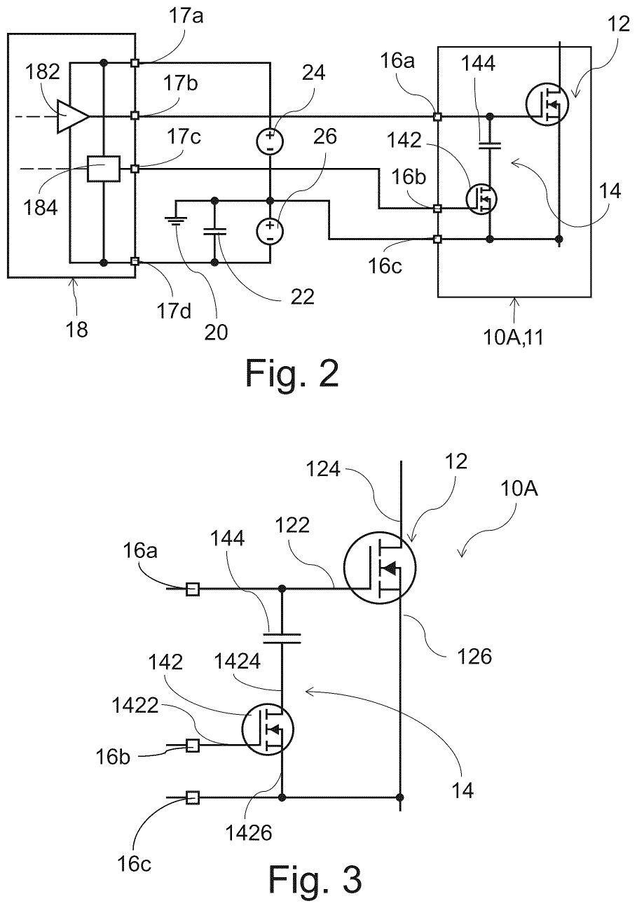

FIG. 2 shows a schematic circuit diagram that contains a module circuit 11 for a half bridge module 10A, the driver module 18, and a clamping circuit 14 integrated in the module circuit 11 according to one embodiment. The half bridge module 10A, enlarged in FIG. 3, contains numerous semiconductor switches 12, only one of which is shown, for purposes of clarity. The semiconductor switch 12 is preferably a transistor, e.g. a MOSFET, HEMT, or IGBT, thus containing a gate terminal 122, a controlled (drain or emitter) terminal 124, and a reference potential terminal (source or collector terminal) 126. The controlled terminal 124 supplies the input current (switching current) flowing through the semiconductor switch 12. The reference potential terminal 126 is connected by a signal pin 16c to the ground 20. The gate terminal 122 is connected by another signal pin 16a, which extends to a connection point 17b to the first control unit 182 in the driver module 18. By this means, the control signals generated by the first control unit 182 can be sent to the semiconductor switches 12.

As also shown schematically in FIGS. 2 and 3, a clamping circuit 14 is integrated in the module circuit 11. The clamping circuit 14 contains a clamping switch 142 and a capacitor 144 connected in series to the clamping circuit 142. The clamping circuit 142 is interconnected between the gate terminal 122 and the reference potential terminal 126 in the semiconductor switch 12. The clamping switch 142 is preferably a transistor, in particular a MOSFET, e.g. an n-MOSFET. The clamping switch 142 has a clamping switch terminal 1422 (gate terminal) for a clamping switch signal, and a positive drain terminal 1424, as well as a negative source terminal 1426. The capacitor 144 is interconnected between the gate terminal 122 for the semiconductor switch 12 and the positive drain terminal 1424 for the clamping switch 142. The clamping switch signal is generated by the second control unit 184 for the clamping switch 142, which is preferably integrated in the driver module, as shown here. Targeted control of the clamping switch results in Active Miller Clamping (AMC) only when switching the complementary switch in the half bridge. The AMC forms an additional path for the Miller current toward the reference potential terminal, which counteracts the voltage spikes, or Miller spikes, described above. The second control unit 184 is connected by a second connection point 17c on a signal pin 16b to the clamping switch 142.

A first voltage supply 24 and second voltage supply 26, are connected in series to the first control unit 182 in the driver module 18 by connection points 17a, 17d, such that the first control unit 182 obtains a positive supply voltage V_{DD} for the first voltage supply 24 and a negative supply voltage V_{EE} for the second voltage supply 26. In addition, a capacitor 22 is connected in parallel to the second voltage supply 26. In this circuit arrangement, the capacitor 144 for the clamping circuit 14 is charged once when the clamping switch 142 is off by the negative supply voltage V_{EE} at the second voltage supply 26 by a diode 1428 intrinsically incorporated in the clamping switch 142. The capacitor 144 is subsequently recharged. The capacitor 144 is fully charged by the negative supply voltage V_{EE} when the clamping switch 144 is switched off long enough. This is obtained with the intrinsic diode 1429 (also referred to as a “body diode”) in the clamping switch 142, in that the clamping switch 142 is only activated if the first control unit 182 in the driver module 18 switches the semiconductor switch 12 off (i.e. when the gate terminal 122 in the semiconductor switch 12 is connected to the negative supply voltage V_{EE}). This results in all of the negative supply voltage V_{EE} being applied to the clamping switch 142.

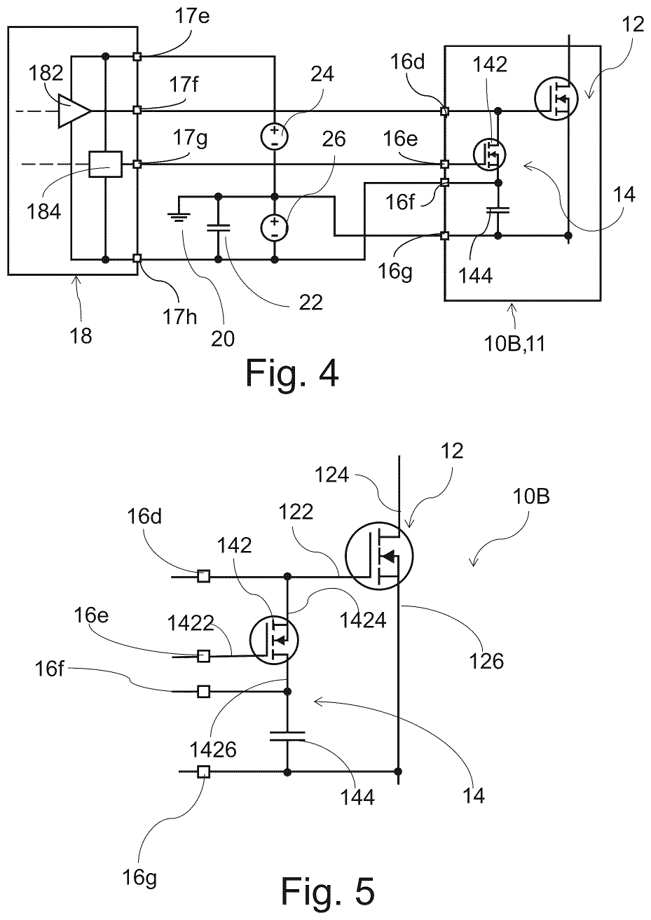

FIG. 4 shows a schematic circuit diagram that contains a module circuit 11 for a half bridge module 10B, the driver module 18, and a clamping circuit 14 integrated in the module circuit 11, according to an alternative embodiment. The half bridge module 10B, enlarged in FIG. 5, contains numerous semiconductor switches 12, as in the embodiment shown in FIGS. 2 and 3, only one of which is shown, for purposes of clarity. The half bridge module 10B is similar to the embodiment shown in FIGS. 2 and 3. The main difference is that the positions of the clamping switch 142 and capacitor 144 are reversed in the clamping circuit 14. Accordingly, instead of three, four signal pins 16d-g are used on the half bridge module 10B. The three terminals 1422, 1424, 1426 for the clamping switch 142 each have a signal pin 16d, 16e, 16f with which they are connected at a connection point 17f, 17g, 17h to the control units 182, 184. There is also a signal pin 16d for the gate terminal 122 on the clamping switch 12. There is another signal pin 16f for an electrode in the capacitor 144 facing the clamping switch 142. The signal pin 16f ensures that the second control unit 184 can control the clamping switch 142 independently of the level of the negative supply voltage V_{EE}. The electrode in the capacitor 144 facing away from the clamping switch 142 and the reference potential terminal 126 on the semiconductor switch 12 have an additional signal pin 16g with which the capacitor and the reference potential terminal 126 on the semiconductor switch 12 are connected to the ground 20.

There are also two voltage generators 24, 26 in the embodiments shown in FIGS. 4 and 5 for generating the positive supply voltage V_{DD} and negative supply voltage V_{EE}, and an additional capacitor 22 is connected in parallel to the second voltage generator 26.

### REFERENCE SYMBOLS

10, 10A, 10B power module/half bridge module
11 module circuit
12 semiconductor switch
122 gate terminal
124 controlled terminal
126 reference potential terminal
14 clamping circuit
142 clamping switch
1422 clamping switch terminal
1424 positive terminal
1426 negative terminal
1428 intrinsic diode
16a-g signal pins
17a-h connection points
18 driver module
182 first control unit
184 second control unit
20 ground
22 capacitor
24 first voltage supply
26 second voltage supply

1. A clamping circuit for a power module, wherein the power module comprises one or more semiconductor switches connected in parallel and a plurality of terminals for an input current and an output current, and a plurality of signal pins for transmitting control signals generated by a driver module to the power module, wherein the semiconductor switches, terminals, and signal pins in the power module form a module circuit, wherein the clamping circuit comprises:
a clamping switch between a gate terminal and a reference potential terminal on a semiconductor switch of the one or more semiconductor switches, wherein the clamping switch is integrated in the module circuit in the power module.

2. The clamping circuit according to claim 1,
wherein a first signal pin for the power module is dedicated to the clamping switch to transmit a clamping signal generated by a control unit spatially separated from the power module to the clamping switch.

3. The clamping circuit according to claim 2, wherein the first signal pin extends from a clamping switch terminal on the clamping switch to the control unit.

4. The clamping circuit according to claim 3, wherein the control unit is integrated in the driver module, and wherein the driver module is spaced apart from the power module.

5. The clamping circuit according to claim 2, comprising:
a capacitor between the clamping switch and the gate terminal or the reference potential terminal on the semiconductor switch.

6. The clamping circuit according to claim 5, comprising:
the capacitor between the clamping switch and the gate terminal on the semiconductor switch;
a second signal pin connected at a module side to both the capacitor and the gate terminal on the semiconductor switch; and
a third signal pin connected at the module side to both a negative terminal on the clamping switch and the reference potential terminal on the semiconductor switch,
wherein the first signal pin is the only signal pin of the first, second, and third signal pins exclusively dedicated to the clamping switch, and
wherein a diode is intrinsically incorporated in the clamping switch.

7. The clamping circuit according to claim 5, comprising:
the capacitor between the clamping switch and the reference potential terminal in the semiconductor switch;
a second signal pin connected at a module side to both a positive terminal on the clamping switch and the gate terminal on the semiconductor switch;
a third signal pin connected at the module side to both a negative terminal on the clamping switch and the capacitor; and
a fourth signal pin connected at the module side to both the capacitor and the reference potential terminal on the semiconductor switch.

8. A power module for a converter, comprising:
one or more semiconductor switches connected in parallel;
a plurality of terminals on the power module for an input current and an output current; and
a plurality of signal pins for transmitting control signals generated by a driver module in the converter to the one or more semiconductor switches,
wherein the one or more semiconductor switches, terminals, and signal pins in the power module form a module circuit, which also comprises the clamping circuit according to claim 1.

9. The clamping circuit according to claim 1,
wherein the power module is insulated with insulation,
wherein the signal pins for the power module extend out of a surface of the insulation, and
wherein the clamping circuit is inside the insulation.

10. A converter for powering an electric drive in an electric vehicle or hybrid vehicle, wherein the converter comprises:
a plurality of phase units and a driver module spatially separated from the plurality of phase units,
wherein each of the plurality of phase units is assigned a current phase, and
wherein the plurality of phase units each have one or more of the power module according to claim 1.

11. An electric axle drive for an electric vehicle or hybrid vehicle, comprising:
an electric motor;
a transmission; and
the converter according to claim 10.

12. An electric vehicle or hybrid vehicle, comprising:
the electric axle drive according to claim 11.

13. The clamping circuit according to claim 2, wherein the control unit is integrated in the driver module, and wherein the driver module is spaced apart from the power module.

14. The clamping circuit according to claim 13, comprising:
a capacitor between the clamping switch and the gate terminal or the reference potential terminal on the semiconductor switch.

15. The clamping circuit according to claim 14, comprising:
the capacitor between the clamping switch and the gate terminal on the semiconductor switch;
a second signal pin connected at a module side to both the capacitor and the gate terminal on the semiconductor switch; and
a third signal pin connected at the module side to both a negative terminal on the clamping switch and the reference potential terminal on the semiconductor switch,
wherein the first signal pin is the only signal pin of the first, second, and third signal pins exclusively dedicated to the clamping switch, and
wherein a diode is intrinsically incorporated in the clamping switch.

16. The clamping circuit according to claim 14, comprising:
the capacitor between the clamping switch and the reference potential terminal in the semiconductor switch;
a second signal pin connected at a module side to both a positive terminal on the clamping switch and the gate terminal on the semiconductor switch;
a third signal pin connected at the module side to both a negative terminal on the clamping switch and the capacitor; and
a fourth signal pin connected at the module side to both the capacitor and the reference potential terminal on the semiconductor switch.

17. The clamping circuit according to claim 3, comprising:
a capacitor between the clamping switch and the gate terminal or the reference potential terminal on the semiconductor switch.

18. The clamping circuit according to claim 17, comprising:
the capacitor between the clamping switch and the gate terminal on the semiconductor switch;
a second signal pin connected at a module side to both the capacitor and the gate terminal on the semiconductor switch; and
a third signal pin connected at the module side to both a negative terminal on the clamping switch and the reference potential terminal on the semiconductor switch,
wherein the first signal pin is the only signal pin of the first, second, and third signal pins exclusively dedicated to the clamping switch, and
wherein a diode is intrinsically incorporated in the clamping switch.

19. The clamping circuit according to claim 17, comprising:
the capacitor between the clamping switch and the reference potential terminal in the semiconductor switch;
a second signal pin connected at a module side to both a positive terminal on the clamping switch and the gate terminal on the semiconductor switch;
a third signal pin connected at the module side to both a negative terminal on the clamping switch and the capacitor; and
a fourth signal pin connected at the module side to both the capacitor and the reference potential terminal on the semiconductor switch.
